(19) United States
(12) Patent Application Publication
(10) Pub. No.: US 2024/0012870 A1
(43) Pub. Date: Jan. 11, 2024

(54) MACHINE-LEARNED APPROXIMATION TECHNIQUES FOR NUMERICAL SIMULATIONS

(71) Applicant: Google LLC, Mountain View, CA (US)

(72) Inventors: Stephan Hoyer, Mountain View, CA (US); Michael Brenner, Mountain View, CA (US); Jamie Smith, Mountain View, CA (US); Dmitrii Kochkov, Mountain View, CA (US)

(21) Appl. No.: 18/253,168

(22) PCT Filed: Jan. 19, 2021
(86) PCT No.: PCT/US2021/013888

§ 371 Date: May 16, 2023

(51) Int. Cl. G06F 17/13

(52) U.S. Cl. CPC G06F 17/13

(57) ABSTRACT

Example embodiments relate to machine-learned approximation techniques for numerical simulations. An example computer-implemented method for performing enhanced numerical simulations includes receiving a first vector field corresponding to a first solution of one or more differential equations at a first time step. The first vector field includes first values at each of a plurality of points along a mesh. The method also includes determining, using a machine-learned model, one or more refinement terms based on the first vector field, wherein the refinement terms represent effects of areas between points on the mesh. In addition, the method includes modifying one or more of the first values at one or more of the plurality of points along the mesh based on the one or more refinement terms. Further, the method includes generating a second vector field that includes second values at each of the plurality of points.

### BACKGROUND

Unless otherwise indicated herein, the materials described in this section are not prior art to the claims in this application and are not admitted to be prior art by inclusion in this section.

Many physical systems can be described by sets of differential equations (e.g., partial differential equations). For example, interactions between electromagnetic fields, electric changes, electromagnetic potential, and/or electric currents may be described using Maxwell's equations. Likewise, the wave equation may be used to describe wavelike phenomena, such as sound, light, a vibrating string, ocean waves, etc. Similarly, Schrodinger's equation can be used to describe quantum-mechanical systems. Further, the Navier-Stokes equations can be used to describe the motion of fluids. Many other examples also exist (e.g., the heat equation, diffusion equation, continuity equation, etc.).

Such differential equations describing physical systems may be solved numerically (e.g., using a computing device) to predict physical quantities (e.g., velocity, voltage, pressure, etc.) in a simulated system. Numerical simulation methods may involve discretizing the differential equations within a physical system, applying boundary conditions, and iteratively solving (e.g., different timesteps) the equation(s) for given inputs. Example numerical methods include the finite difference method, the finite volume method, the finite element method, and the method of moments.

Additionally, machine learning is a field in computing that involves a computing device training a model using “training data.” There are two primary classifications of methods of training models: supervised learning and unsupervised learning. In supervised learning, the training data is classified into data types, and the model is trained to look for variations/similarities among known classifications. In unsupervised learning, the model is trained using training data that is unclassified. Thus, in unsupervised learning, the model is trained to identify similarities based on unlabeled training data.

Once the model has been trained on the training data, the model can then be used to analyze new data (sometimes called “test data”). Based on the model's training, a computing device can use the trained model to evaluate the similarity of the test data.

There are numerous types of machine-learned models, each having its own set of advantages and disadvantages. One popular machine-learned model is an artificial neural network. The artificial neural network involves layers of structure, each trained to identify certain features of an input (e.g., an input image, an input sound file, or an input text file). Each layer may be built upon sub-layers that are trained to identify sub-features of a given feature. For example, an artificial neural network may identify composite objects within an image based on sub-features such as edges or textures.

Given the current state of computing power, in some artificial neural networks many such sub-layers can be established during training of a model. Artificial neural networks that include multiple sub-layers are sometimes referred to as “deep neural networks.” In some deep neural networks, there may be hidden layers and/or hidden sub-layers that identify composites or superpositions of inputs. Such composites or superpositions may not be human-interpretable.

### SUMMARY

This disclosure relates to machine-learned approximation techniques for numerical simulations. When performing a numerical simulation (e.g., to solve Maxwell's equations or Navier-Stokes equations), using a dense mesh of points may be overly computationally burdensome. However, using a sparse mesh may sacrifice accuracy. Provided herein are techniques that allow for refinement of numerical solutions to differential equations using machine-learned models. For example, a machine-learned model may be trained (e.g., using complete numerical solutions of high-density meshes as training data) to perform interpolations between two or more points of a mesh. In run-time, the machine-learned model may determine refinement terms based on interpolations between points on a mesh (e.g., a low-density mesh) that were solved for using the numerical method. Using the refinement terms, the solution to the differential equation(s) on the points of the mesh may be updated to more accurately model the physical system.

In one aspect, a computer-implemented method for performing enhanced numerical simulations is provided. The method includes receiving a first vector field corresponding to a first solution of one or more differential equations at a first time step. The first vector field includes first values at each of a plurality of points along a mesh. The method also includes determining, using a machine-learned model, one or more refinement terms based on the first vector field. The refinement terms represent effects of areas between points on the mesh on solutions to the one or more differential equations. In addition, the method includes modifying one or more of the first values at one or more of the plurality of points along the mesh based on the one or more refinement terms. Further, the method includes solving the one or more differential equations at a second time step based on the first values at each of the plurality of points to determine a second vector field that includes second values at each of the plurality of points.

In another aspect, an article of manufacture that includes a non-transitory, computer-readable medium having stored therein instructions executable by a computing device to cause the computing device to perform a computer-implemented method for performing enhanced numerical simulations is provided. The method includes receiving a first vector field corresponding to a first solution of one or more differential equations at a first time step. The first vector field includes first values at each of a plurality of points along a mesh. The method also includes determining, using a machine-learned model, one or more refinement terms based on the first vector field. The refinement terms represent effects of areas between points on the mesh on solutions to the one or more differential equations. In addition, the method includes modifying one or more of the first values at one or more of the plurality of points along the mesh based on the one or more refinement terms. Further, the method includes solving the one or more differential equations at a second time step based on the first values at each of the plurality of points to determine a second vector field that includes second values at each of the plurality of points.

In an additional aspect, a system is provided. The system includes one or more processors. The system also includes a non-transitory, computer-readable medium having stored therein instructions executable by the one or more processors to perform a computer-implemented method for performing enhanced numerical simulations. The method includes receiving a first vector field corresponding to a first solution of one or more differential equations at a first time step. The first vector field includes first values at each of a plurality of points along a mesh. The method also includes determining, using a machine-learned model, one or more refinement terms based on the first vector field. The refinement terms represent effects of areas between points on the mesh on solutions to the one or more differential equations. In addition, the method includes modifying one or more of the first values at one or more of the plurality of points along the mesh based on the one or more refinement terms. Further, the method includes solving the one or more differential equations at a second time step based on the first values at each of the plurality of points to determine a second vector field that includes second values at each of the plurality of points.

These as well as other aspects, advantages, and alternatives will become apparent to those of ordinary skill in the art by reading the following detailed description, with reference, where appropriate, to the accompanying drawings.

### BRIEF DESCRIPTION OF THE DRAWINGS

FIG. 1 is a diagram illustrating training and inference phases of a machine-learning model, according to example embodiments.

FIG. 2 is a simplified block diagram showing some of the components of a computing device, according to example embodiments.

FIG. 3 is an illustration of a numerical simulation, according to example embodiments.

FIG. 4A is a flowchart illustration of a method of refining a numerical simulation by interpolation, according to example embodiments.

FIG. 4B is a flowchart illustration of a method of refining a numerical simulation by interpolation using a machine-learned model, according to example embodiments.

FIG. 4C is a flowchart illustration of a method of refining a numerical simulation of a turbulent flow by interpolation using a machine-learned model, according to example embodiments.

FIG. 5A is a diagram of a marker-and-cell method used in interpolations, according to example embodiments.

FIG. 5B is a diagram of a face-centered interpolation of convective flux, according to example embodiments.

FIG. 5C is a diagram of a face-centered interpolation of convective flux, according to example embodiments.

FIG. 6 is a flowchart illustration of a method, according to example embodiments.

FIG. 7 illustrates experimental results, according to example embodiments.

### DETAILED DESCRIPTION

Example methods and systems are contemplated herein. Any example embodiment or feature described herein is not necessarily to be construed as preferred or advantageous over other embodiments or features. The example embodiments described herein are not meant to be limiting. It will be readily understood that certain aspects of the disclosed systems and methods can be arranged and combined in a wide variety of different configurations, all of which are contemplated herein.

Furthermore, the particular arrangements shown in the figures should not be viewed as limiting. It should be understood that other embodiments might include more or less of each element shown in a given figure. Further, some of the illustrated elements may be combined or omitted. Yet further, an example embodiment may include elements that are not illustrated in the figures.

### I. Overview

Numerical simulations of differential equations (e.g., partial differential equations) may be performed to determine the results of a physical system according to a given set of inputs and boundary conditions. For example, solutions to Maxwell's equations, Navier-Stokes equations, diffusion equations, heat equations, etc. may be represented using numerical simulations. Performing such numerical simulations may include discretizing the equations along a plurality of points (e.g., points on a mesh) and solving the differential equations at those points. Some example numerical simulation techniques include the finite difference method, the finite volume method, the finite element method, spectral methods, pseudo-spectral methods, discontinuous Galerkin methods, and the method of moments. Other numerical simulation techniques are also possible. Further, such numerical simulations may involve a large amount of computations (e.g., a large number of matrix multiplications). Hence, such numerical simulations are frequently performed by a computing device (e.g., one or more processors executing a series of instructions stored on a non-transitory, computer-readable medium).

In order to fully resolve every aspect of a system using a discretized numerical simulation technique, the discretization step (e.g., the distance between points along a mesh) needs to be substantially smaller than any scale over which the differential equation might vary significantly (e.g., to ensure that discontinuities or other features of the system are captured by the discretization). However, in order to discretize at such a small scale, a substantial amount of compute power/compute time may be required to solve the resulting system of differential equations. As such, there has historically been a trade off between highly resolved, very accurate solutions for numerical simulations and feasibility of computation.

Based on the above, in order to save computing resources, less-accurate simulations on more sparsely positioned points may be performed. In order to improve accuracy on less-dense meshes of points, though, some interpolation algorithms may be performed. Such interpolations may influence solutions to the differential equations (e.g., solutions at a second time step) based on a priori intuition into the relevant physical system. For example, if solutions to a set of differential equations typically follow a polynomial form, the interpolations may include a set of coefficients for the corresponding polynomial form, where the coefficients are determined based on adjacent points along the mesh. While such interpolations may improve the accuracy of less-dense meshes, they too can suffer from being computationally expensive to calculate and/or may not be sufficiently flexible to provide accurate interpretations across the entire mesh of points (e.g., a polynomial form with given coefficients that may apply in one part of the mesh may not apply across the entire mesh).

Provided herein are techniques that allow for improved accuracy of numerical simulations for less-dense meshes without requiring significant additional computational resources. The techniques described herein include determining refinement terms based on values of points in a mesh while solving the differential equations. The refinement terms may represent interpolations between two or more points or values along the mesh. Additionally or alternatively, the refinement terms may reflect variations along small scales in the simulation. These refinement terms may be used to calculate the solution(s) to the discretized differential equation(s) (e.g., may be used to calculate the solution of the differential equations at a next time step in the simulation).

As described herein, a machine-learned model (e.g., an artificial neural network) may be used to determine these refinement terms. For example, the machine-learned model may take as an input a vector field corresponding to a series of points along a mesh that represent a discretized solution of one or more differential equations. Each point may have given values that represent different facets of the solution to the differential equations (e.g., velocity, force, pressure, electric charge, electric current, etc.). The machine-learned model may then determine the refinement terms (e.g., interpolations) based on the vector field.

Such a machine-learned model may be trained using very-dense, discretized numerical simulations of similar physical systems and/or related differential equations. For example, a machine-learned model may be trained on training data that includes a plurality of numerical solutions for Navier-Stokes equations having very small simulated separations between points (e.g., less than the Kolmogorov lengthscale, η). In this way, the machine-learned model may incorporate substantial physical intuition (i.e., relevant physical priors) that is built into the training data. However, when determining the refinement terms in runtime, because the training of the machine-learned model happened previously (during a training phase of the machine-learned model), less computational resources are required while performing the numerical simulation (e.g., less memory occupied/allocated, less processing time, fewer processing cores used, etc.).

As such, using the techniques described herein, the accuracy of a less-dense numerical simulation can be improved over other conventional interpolation techniques that are less reliable. Further, the accuracy of the less-dense numerical simulation better approximates a more-dense numerical simulation without requiring the additional computational resources of the more-dense numerical simulation.

### II. Example Systems

The following description and accompanying drawings will elucidate features of various example embodiments. The embodiments provided are by way of example, and are not intended to be limiting. As such, the dimensions of the drawings are not necessarily to scale.

A machine-learned model as described herein may include, but is not limited to: an artificial neural network (e.g., a convolutional neural network, a recurrent neural network, a Bayesian network, a hidden Markov model, a Markov decision process, a logistic regression function, a suitable statistical machine-learning algorithm, and/or a heuristic machine-learning system), a support vector machine, a regression tree, an ensemble of regression trees (also referred to as a regression forest), a decision tree, an ensemble of decision trees (also referred to as a decision forest), or some other machine-learning model architecture or combination of architectures.

An artificial neural network (ANN) could be configured in a variety of ways. For example, the ANN could include two or more layers, could include units having linear, logarithmic, or otherwise-specified output functions, could include fully or otherwise-connected neurons, could include recurrent and/or feed-forward connections between neurons in different layers, could include filters or other elements to process input information and/or information passing between layers, or could be configured in some other way to facilitate the generation of predicted color palettes based on input images.

An ANN could include one or more filters that could be applied to the input and the outputs of such filters could then be applied to the inputs of one or more neurons of the ANN. For example, such an ANN could be or could include a convolutional neural network (CNN). Convolutional neural networks are a variety of ANNs that are configured to facilitate ANN-based classification or other processing based on images or other large-dimensional inputs whose elements are organized within two or more dimensions. The organization of the ANN along these dimensions may be related to some structure in the input structure (e.g., as relative location within the two-dimensional space of an image can be related to similarity between pixels of the image).

In example embodiments, a CNN includes at least one two-dimensional (or higher-dimensional) filter that is applied to an input; the filtered input is then applied to neurons of the CNN (e.g., of a convolutional layer of the CNN). The convolution of such a filter and an input could represent the color values of a pixel or a group of pixels from the input, in embodiments where the input is an image. A set of neurons of a CNN could receive respective inputs that are determined by applying the same filter to an input. Additionally or alternatively, a set of neurons of a CNN could be associated with respective different filters and could receive respective inputs that are determined by applying the respective filter to the input. Such filters could be trained during training of the CNN or could be pre-specified. For example, such filters could represent wavelet filters, center-surround filters, biologically-inspired filter kernels (e.g., from studies of animal visual processing receptive fields), or some other pre-specified filter patterns.

A CNN or other variety of ANN could include multiple convolutional layers (e.g., corresponding to respective different filters and/or features), pooling layers, rectification layers, fully connected layers, or other types of layers. Convolutional layers of a CNN represent convolution of an input image, or of some other input (e.g., of a filtered, downsampled, or otherwise-processed version of an input image), with a filter. Pooling layers of a CNN apply non-linear downsampling to higher layers of the CNN, e.g., by applying a maximum, average, L2-norm, or other pooling function to a subset of neurons, outputs, or other features of the higher layer(s) of the CNN. Rectification layers of a CNN apply a rectifying nonlinear function (e.g., a non-saturating activation function, a sigmoid function) to outputs of a higher layer. Fully connected layers of a CNN receive inputs from many or all of the neurons in one or more higher layers of the CNN. The outputs of neurons of one or more fully connected layers (e.g., a final layer of an ANN or CNN) could be used to determine information about areas of an input image (e.g., for each of the pixels of an input image) or for the image as a whole.

Neurons in a CNN can be organized according to corresponding dimensions of the input. For example, where the input is an image (a two-dimensional input, or a three-dimensional input where the color channels of the image are arranged along a third dimension), neurons of the CNN (e.g., of an input layer of the CNN, of a pooling layer of the CNN) could correspond to locations in the two-dimensional input image. Connections between neurons and/or filters in different layers of the CNN could be related to such locations. For example, a neuron in a convolutional layer of the CNN could receive an input that is based on a convolution of a filter with a portion of the input image, or with a portion of some other layer of the CNN, that is at a location proximate to the location of the convolutional-layer neuron. In another example, a neuron in a pooling layer of the CNN could receive inputs from neurons, in a layer higher than the pooling layer (e.g., in a convolutional layer, in a higher pooling layer), that have locations that are proximate to the location of the pooling-layer neuron.

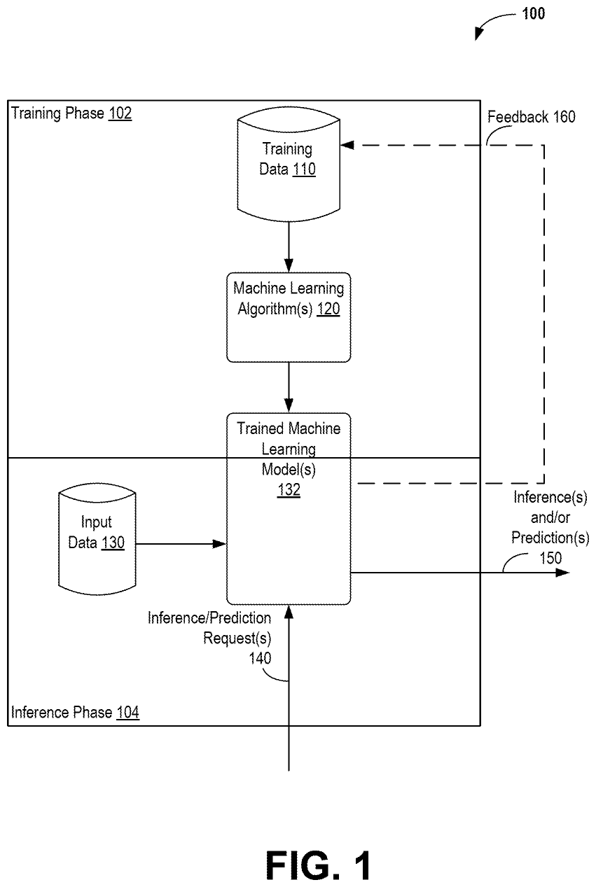

FIG. 1 shows diagram 100 illustrating a training phase 102 and an inference phase 104 of trained machine-learning model(s) 132, in accordance with example embodiments. Some machine-learning techniques involve training one or more machine-learning algorithms, on an input set of training data to recognize patterns in the training data and provide output inferences and/or predictions about (patterns in the) training data. Such output could take the form of filtered or otherwise modified versions of the input (e.g., an input image could be modified by the machine-learning model to appear as though foreground content is in-focus while background content is out of focus). The resulting trained machine-learning algorithm can be termed as a trained machine-learning model or, simply, a machine-learned model. For example, FIG. 1 shows training phase 102 where one or more machine-learning algorithms 120 are being trained on training data 110 to become trained machine-learning model 132. Then, during inference phase 104, trained machine-learning model 132 can receive input data 130 and one or more inference/prediction requests 140 (e.g., as part of input data 130) and responsively provide as an output one or more inferences and/or predictions 150.

As such, trained machine-learning model(s) 132 can include one or more models of one or more machine-learning algorithms 120. Machine-learning algorithm(s) 120 may include, but are not limited to: an artificial neural network (e.g., a herein-described convolutional neural networks, a recurrent neural network, a Bayesian network, a hidden Markov model, a Markov decision process, a logistic regression function, a suitable statistical machine-learning algorithm, and/or a heuristic machine-learning system), a support vector machine, a regression tree, an ensemble of regression trees (also referred to as a regression forest), a decision tree, an ensemble of decision trees (also referred to as a decision forest), or some other machine-learning model architecture or combination of architectures. Machine-learning algorithm(s) 120 may be supervised or unsupervised, and may implement any suitable combination of online and offline learning.

In some examples, machine-learning algorithm(s) 120 and/or trained machine-learning model(s) 132 can be accelerated using on-device coprocessors, such as graphic processing units (GPUs), tensor processing units (TPUs), digital signal processors (DSPs), and/or application specific integrated circuits (ASICs). Such on-device coprocessors can be used to speed up machine-learning algorithm(s) 120 and/or trained machine-learning model(s) 132. In some examples, trained machine-learning model(s) 132 can be trained, reside and execute to provide inferences on a particular computing device, and/or otherwise can make inferences for the particular computing device.

During training phase 102, machine-learning algorithm(s) 120 can be trained by providing at least training data 110 as training input using unsupervised, supervised, semi-supervised, and/or reinforcement learning techniques. Unsupervised learning involves providing a portion (or all) of training data 110 to machine-learning algorithm(s) 120 and machine-learning algorithm(s) 120 determining one or more output inferences based on the provided portion (or all) of training data 110. Supervised learning involves providing a portion of training data 110 to machine-learning algorithm(s) 120, with machine-learning algorithm(s) 120 determining one or more output inferences based on the provided portion of training data 110, and the output inference(s) are either accepted or corrected based on correct results associated with training data 110. In some examples, supervised learning of machine-learning algorithm(s) 120 can be governed by a set of rules and/or a set of labels for the training input, and the set of rules and/or set of labels may be used to correct inferences of machine-learning algorithm(s) 120.

Semi-supervised learning involves having correct results for part, but not all, of training data 110. During semi-supervised learning, supervised learning is used for a portion of training data 110 having correct results, and unsupervised learning is used for a portion of training data 110 not having correct results. Reinforcement learning involves machine-learning algorithm(s) 120 receiving a reward signal regarding a prior inference, where the reward signal can be a numerical value. During reinforcement learning, machine-learning algorithm(s) 120 can output an inference and receive a reward signal in response, where machine-learning algorithm(s) 120 are configured to try to maximize the numerical value of the reward signal. In some examples, reinforcement learning also utilizes a value function that provides a numerical value representing an expected total of the numerical values provided by the reward signal over time. In some examples, machine-learning algorithm(s) 120 and/or trained machine-learning model(s) 132 can be trained using other machine-learning techniques, including but not limited to, incremental learning and curriculum learning.

In some examples, machine-learning algorithm(s) 120 and/or trained machine-learning model(s) 132 can use transfer-learning techniques. For example, transfer-learning techniques can involve trained machine-learning model(s) 132 being pre-trained on one set of data and additionally trained using training data 110. More particularly, machine-learning algorithm(s) 120 can be pre-trained on data from one or more computing devices and a resulting trained machine-learning model provided to computing device CD1, where CD1 is intended to execute the trained machine-learning model during inference phase 104. Then, during training phase 102, the pre-trained machine-learning model can be additionally trained using training data 110, where training data 110 can be derived from kernel and non-kernel data of computing device CD1. This further training of the machine-learning algorithm(s) 120 and/or the pre-trained machine-learning model using training data 110 of CD1's data can be performed using either supervised or unsupervised learning. Once machine-learning algorithm(s) 120 and/or the pre-trained machine-learning model has been trained on at least training data 110, training phase 102 can be completed. The trained resulting machine-learning model can be utilized as at least one of trained machine-learning model(s) 132.

In particular, once training phase 102 has been completed, trained machine-learning model(s) 132 can be provided to a computing device, if not already on the computing device. Inference phase 104 can begin after trained machine-learning model(s) 132 are provided to computing device CD1.

During inference phase 104, trained machine-learning model(s) 132 can receive input data 130 and generate and output one or more corresponding inferences and/or predictions 150 about input data 130. As such, input data 130 can be used as an input to trained machine-learning model(s) 132 for providing corresponding inference(s) and/or prediction(s) 150 to kernel components and non-kernel components. For example, trained machine-learning model(s) 132 can generate inference(s) and/or prediction(s) 150 in response to one or more inference/prediction requests 140. In some examples, trained machine-learning model(s) 132 can be executed by a portion of other software. For example, trained machine-learning model(s) 132 can be executed by an inference or prediction daemon to be readily available to provide inferences and/or predictions upon request. Input data 130 can include data from computing device CD1 executing trained machine-learning model(s) 132 and/or input data from one or more computing devices other than CD1.

Input data 130 can include a collection of images provided by one or more sources. The collection of images can include video frames, images resident on computing device CD1, and/or other images. Other types of input data are possible as well.

Inference(s) and/or prediction(s) 150 can include output images, output intermediate images, numerical values, and/or other output data produced by trained machine-learning model(s) 132 operating on input data 130 (and training data 110). In some examples, trained machine-learning model(s) 132 can use output inference(s) and/or prediction(s) 150 as input feedback 160. Trained machine-learning model(s) 132 can also rely on past inferences as inputs for generating new inferences.

A conditioned, axial self-attention based neural network can be an example of machine-learning algorithm(s) 120. After training, the trained version of the neural network can be an example of trained machine-learning model(s) 132. In this approach, an example of inference/prediction request(s) 140 can be a request to predict one or more colorizations of a grayscale image and a corresponding example of inferences and/or prediction(s) 150 can be an output image including the one or more colorizations of the grayscale image.

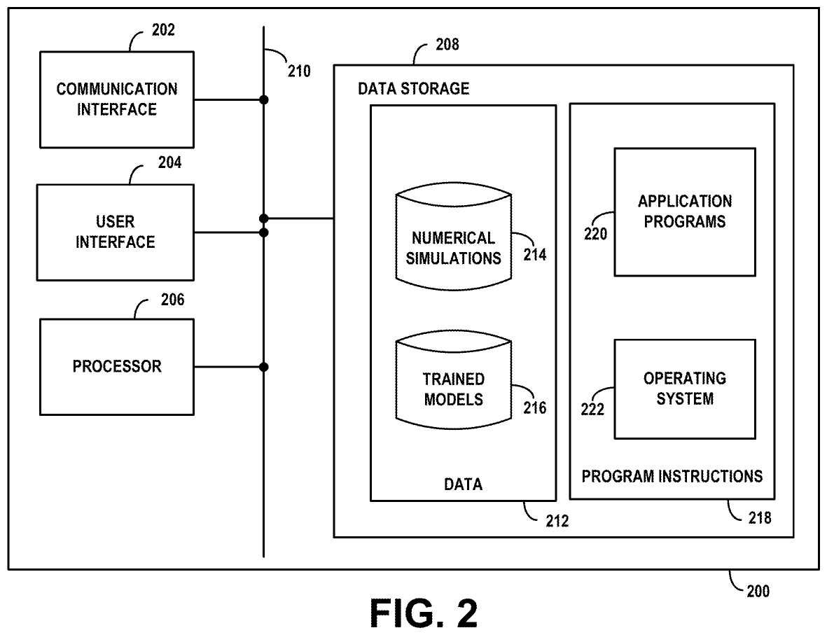

FIG. 2 illustrates an example computing device 200 that may be used to implement the methods described herein. By way of example and without limitation, computing device 200 may be a cellular mobile telephone (e.g., a smartphone), a computer (such as a desktop, notebook, tablet, or handheld computer, a server), elements of a cloud computing system, a robot, a drone, an autonomous vehicle, or some other type of device. It should be understood that computing device 200 may represent a physical computing device such as a server, a particular physical hardware platform on which a machine-learning application operates in software, or other combinations of hardware and software that are configured to carry out machine-learning functions as described herein.

As shown in FIG. 2, computing device 200 may include a communication interface 202, a user interface 204, a processor 206, and data storage 208, all of which may be communicatively linked together by a system bus, network, or other connection mechanism 210.

Communication interface 202 may function to allow computing device 200 to communicate, using analog or digital modulation of electric, magnetic, electromagnetic, optical, or other signals, with other devices, access networks, and/or transport networks. Thus, communication interface 202 may facilitate circuit-switched and/or packet-switched communication, such as plain old telephone service (POTS) communication and/or Internet protocol (IP) or other packetized communication. For instance, communication interface 202 may include a chipset and antenna arranged for wireless communication with a radio access network or an access point. Also, communication interface 202 may take the form of or include a wireline interface, such as an Ethernet, Universal Serial Bus (USB), or High-Definition Multimedia Interface (HDMI) port. Communication interface 202 may also take the form of or include a wireless interface, such as a Wifi, BLUETOOTH®, global positioning system (GPS), or wide-area wireless interface (e.g., WiMAX or 3GPP Long-Term Evolution (LTE)). However, other forms of physical layer interfaces and other types of standard or proprietary communication protocols may be used over communication interface 202. Furthermore, communication interface 202 may include multiple physical communication interfaces (e.g., a Wifi interface, a BLUETOOTH® interface, and a wide-area wireless interface).

In some embodiments, communication interface 202 may function to allow computing device 200 to communicate with other devices, remote servers, access networks, and/or transport networks. For example, the communication interface 202 may function to access one or more machine-learning models and/or input therefor via communication with a remote server or other remote device or system in order to allow the computing device 200 to use the machine-learned model to generate outputs (e.g., class values for inputs, filtered or otherwise modified versions of image inputs) based on input data. For example, the computing device 200 could be an image server and the remote system could be a smartphone containing an image to be applied to a machine-learning model.

User interface 204 may function to allow computing device 200 to interact with a user, for example to receive input from and/or to provide output to the user. Thus, user interface 204 may include input components such as a keypad, keyboard, touch-sensitive or presence-sensitive panel, computer mouse, trackball, joystick, microphone, and so on. User interface 204 may also include one or more output components such as a display screen which, for example, may be combined with a presence-sensitive panel. The display screen may be based on cathode-ray tube (CRT), liquid-crystal display (LCD), light-emitting diode (LED) technologies, and/or other technologies now known or later developed. User interface 204 may also be configured to generate audible output(s), via a speaker, speaker jack, audio output port, audio output device, earphones, and/or other similar devices.

Processor 206 may include one or more general purpose processors (e.g., microprocessors) and/or one or more special purpose processors (e.g., DSPs, GPUs, floating point units (FPUs), network processors, TPUs, or ASICs). In some instances, special purpose processors may be capable of image processing, image alignment, merging images, executing artificial neural networks, or executing convolutional neural networks, among other applications or functions. Data storage 208 may include one or more volatile and/or non-volatile storage components, such as magnetic, optical, flash, or organic storage, and may be integrated in whole or in part with processor 206. Data storage 208 may include removable and/or non-removable components.

Processor 206 may be capable of executing program instructions 218 (e.g., compiled or non-compiled program logic and/or machine code) stored in data storage 208 to carry out the various functions described herein. Therefore, data storage 208 may include a non-transitory, computer-readable medium, having stored thereon program instructions that, upon execution by computing device 200, cause computing device 200 to carry out any of the methods, processes, or functions disclosed in this specification and/or the accompanying drawings. The execution of program instructions 218 by processor 206 may result in processor 206 using data 212.

By way of example, program instructions 218 may include an operating system 222 (e.g., an operating system kernel, device driver(s), and/or other modules) and one or more application programs 220 (e.g., functions for executing trained machine-learning models) installed on computing device 200. Data 212 may include input numerical simulations 214 and/or one or more trained machine-learning models 216. Numerical simulations 214 may be used to train machine-learning models and/or may be applied to such a trained machine-learning model in order to generate a class for the numerical simulation or to generate some other model output as described herein.

Application programs 220 may communicate with operating system 222 through one or more application programming interfaces (APIs). These APIs may facilitate, for instance, application programs 220 reading and/or writing a trained machine-learning model 216, transmitting or receiving information via communication interface 202, receiving and/or displaying information on user interface 204, and so on.

Application programs 220 may take the form of “apps” that could be downloadable to computing device 200 through one or more online application stores or application markets (via, e.g., the communication interface 202). However, application programs can also be installed on computing device 200 in other ways, such as via a web browser or through a physical interface (e.g., a USB port) of the computing device 200.

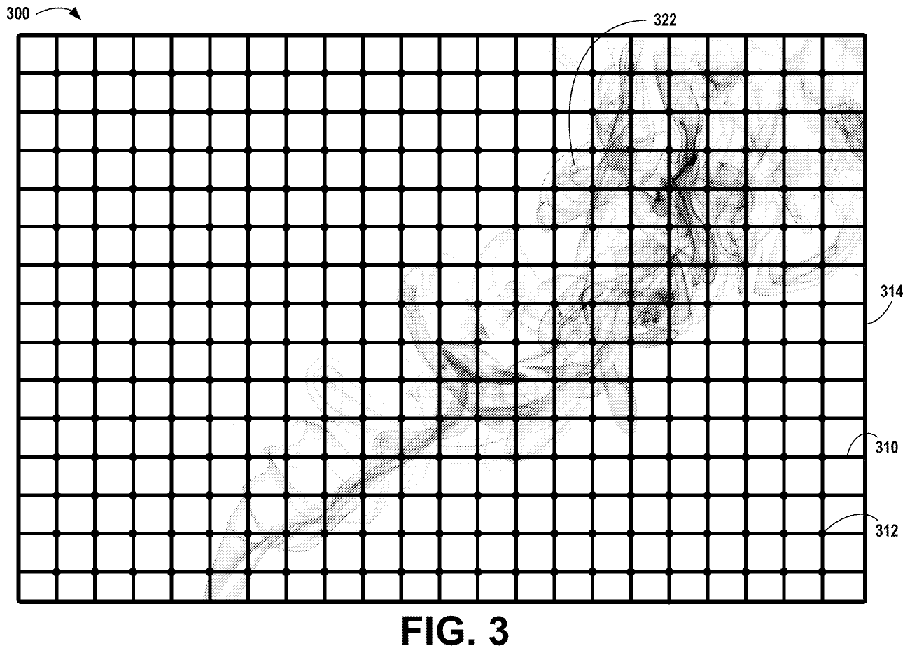

FIG. 3 is an illustration of a numerical simulation 300, according to example embodiments. The numerical simulation 300 may include discretizing one or more differential equations along a mesh 310 of points 312. Further, the numerical simulation 300 may include imposing one or more boundary conditions 314 on the solution. In addition, in some embodiments, the numerical simulation 300 may perform interpolations between points to enhance an accuracy of the solution. One such interpolation may occur, for example, at subgrid positions 322, as illustrated. It is understood that the grid spacing of the mesh 310 and the location of the points 312 along the mesh 310 is provided solely as an example and that other mesh spacings and point locations are also possible and are contemplated herein. Further, in some embodiments, the points may be spaced unevenly across the mesh and/or the grid spacing of the mesh may be uneven across the simulation. Additionally or alternatively, while the mesh 310 in FIG. 3 is generated by intersecting perpendicular horizontal and vertical lines, other embodiments are also possible (e.g., triangular meshes, hexagonal meshes, irregular meshes, or meshes where grid points are adaptively added or removed based on the solution or boundary conditions (i.e., adaptive meshes)).

The numerical simulation 300 may be used to solve for various physical quantities at various points 312 within a physical system. For example, the numerical simulation 300 illustrated in FIG. 3 is a numerical simulation of a turbulent flow within a fluid (e.g., the turbulent flow of smoke particles within air). Hence, the numerical simulation 300 may include determining the velocity and/or pressure at each point 312 within the numerical simulation 300. In various embodiments, the numerical simulations may solve for turbulent flows of various fluids (e.g., liquids or gases) and/or objects within turbulent flows of fluids. Such turbulent flows may be governed by one or more differential equations (e.g., one or more partial differential equations). For example, such turbulent flows may be described by the incompressible Navier-Stokes equations.

The discretization of the points 312 along the mesh 310 may correspond to a finite difference method of numerical simulation of the one or more differential equations. Alternatively, the discretization of the mesh 310 may correspond to a finite element method of numerical simulation. In other embodiments, a finite volume method may be used to solve the one or more differential equations within the numerical simulation. Other numerical methods are also possible and are contemplated herein (e.g., the method of moments).

In the finite difference method, differential equations are converted into a set of linear equations that are solved algebraically using tensors (e.g., matrices), where each element in the various tensors represents a given value (e.g., a physical value such as velocity or pressure) corresponding to a point 312 along the mesh 310. It is understood that the values corresponding to each point throughout this disclosure may correspond to scalars (e.g., electric charges) or vectors (e.g., velocities), depending on context. The conversion to a set of linear equations can be performed by determining a taylor series expansion/approximation of the relevant differential equations, for example. By solving the system of equations described by the tensors, solutions to the one or more differential equations at each point 312 along the mesh 310 can be obtained, thereby resulting in a physical representation of the system in question.

Relatedly, in a finite element method, the system is broken up into smaller “finite elements” by constructing a mesh. A system of algebraic equations is determined to describe each of the finite elements, and then these smaller systems of equations are subsumed into a larger system of equations to model the entire system. Lastly, variational methods are used to determine a solution for this entire system of equations that minimizes an error function. The solution that minimizes the error function is determined to be the most accurate simulation of the system.

Further, in a finite volume method, a system is discretized into a number of “finite volumes” along a mesh (e.g., a three-dimensional mesh). Then, to determine values at each of the finite volumes, volumetric integral descriptions of the governing differential equations are determined. These volumetric integral descriptions are converted to surface integrals using the divergence theorem. Next, using the surface integrals, the relation among finite volumes in the mesh can be described algebraically by describing the flux between each finite volume relative to the finite volumes adjacent to it. This algebraic description can then be solved (e.g., using matrix algebra). In some embodiments, a finite volume method simulation may be performed using the marker-and-cell method, in which certain values (e.g., pressures) are represented at the center of a finite volume and certain values (e.g., velocities) are represented at the faces of the finite volume (e.g., to calculate the fluxes between adjacent finite volumes).

Regardless of what numerical simulation technique is employed, numerical simulations need to account for boundary conditions 314. The boundary conditions 314 may determine how points 312 along edges of the simulation behave when generating the solution. Further, the boundary conditions 314 may be imposed such that the generated solution makes physical sense and/or to simplify the simulation by not imposing discontinuous boundaries. One example boundary condition 314 that may be used is a periodic boundary condition, which sets the boundaries at each edge of the simulation equal to the values of adjacent points from the opposing edges of the simulation. For example, a periodic boundary condition may state that the velocity (e.g., in a turbulent flow simulation) at x₀ is the same as the velocity at xₘₐₓ, and likewise for y₀ and yₘₐₓ. Other boundary conditions (e.g., port boundary conditions, Dirichlet boundary conditions, Neumann boundary conditions, etc.) are also possible and are contemplated herein.

While FIG. 3 illustrates a two-dimensional simulation, it is understood that other dimensionality is possible and contemplated herein. For example, a numerical method (e.g., a finite difference method) representing one spatial dimension may be performed to simulate a physical system. Alternatively, a numerical method (e.g., a finite volume method) representing three spatial dimensions may be performed to simulate a physical system. Depending on the context, one type of numerical simulation method and/or a given dimensionality may be better suited to the physical system than another. The term “point” is used throughout this disclosure to describe a single discretized section of the simulation. It is understood that this term encapsulates “finite volume,” “finite element,” “two-dimensional point,” “one-dimensional point,” “cell face,” “cell volume,” etc. based on whichever simulation technique is being employed. For example, a “plurality of points along a mesh” could correspond to a plurality of finite volumes defined along a three-dimensional mesh within a finite volume method simulation.

Further, while FIG. 3 illustrates a static two-dimensional simulation, it is understood that steady-state and/or time-dependent numerical simulations could also be performed (e.g., to simulate how a physical system evolves over time). In a time-dependent numerical simulation, a similar mesh of points may be evaluated iteratively at each step in time. Alternatively, in some embodiments, the arrangement of the mesh and/or the arrangement of the points on the mesh may be varied between time steps to accommodate one or more changes to values of the points in the solution to the one or more differential equations at a previous time step.

While turbulent fluid flow is the primary example embodiment described herein, and is the embodiment illustrated in FIG. 3, it is understood that, in other embodiments, other types of physical systems are also possible and are contemplated herein. Solutions to many different differential equations that represent physical phenomena can be simulated. For example, light propagation, sound propagation, heat propagation, ocean wave propagation, mechanical vibrations, quantum-mechanical phenomena, etc. can all be modeled using the augmented numerical simulation techniques described herein. In one additional embodiment, for example, electromagnetic fields, electromagnetic forces, electromagnetic potential, and/or electric charges may be described using one or more of Maxwell's equations. In a similar fashion, these Maxwell's equations may be discretized and solved over a mesh of points according to a numerical simulation method (e.g., the finite difference method, the finite element method, the finite volume method, the method of moments, etc.).

As described above, FIG. 3 may illustrate a finite difference method. Alternatively, the numerical simulation used may be a finite volume method. Regardless, simulation techniques such as these include inherent discretizations. The discretizations may be relatively spatially dense or sparse, depending on the lengths (e.g., in x and y directions in two dimensions or in x, y, and z directions in three dimensions) selected between adjacent points 312 on the mesh 310. Further, in time-evolving simulations, the discretizations in time may also be relatively dense or sparse, depending on the time step selected between subsequent iterations. Traditionally (i.e., using a pure direct numerical simulation), the less dense the set of points 312 along the mesh 310 that is used for the simulation, the less computationally expensive (e.g., due to fewer arithmetic operations), but also the less accurate, the numerical simulation becomes (e.g., due to numerical approximations and/or substantial variations, such as discontinuities, that occur over the simulation at a subgrid scale). Hence, traditionally, to maximize the accuracy of the numerical simulation, a densely packed set of points 312 would be selected and additional computational resources would be allotted. For example, in a traditional turbulent flow characterized using Navier-Stokes equations, a mesh 310 having points 312 spaced by an amount less than the Kolmogorov lengthscale (n) may be selected to ensure that the simulation converges to the exact solution, but may also be computationally expensive (e.g., prohibitively computationally expensive).

In order to use more sparse distributions of points 312 (e.g., to save on computation), but retain enhanced accuracy with that sparser distribution, multiple techniques are described herein. For example, interpolated values at subgrid positions 322 between points 312 on the mesh 310 may be determined. These interpolated values may be determined heuristically by applying the values at adjacent points 312 to an approximation (e.g., a polynomial approximation). Further, the influence of the determined interpolated values at the subgrid positions 322 may, in turn, influence the solutions determined at each of the points 312 on the mesh 310 (e.g., in a subsequent iteration of the numerical simulation, such as at the next time step). While only a single subgrid position 322 is illustrated in FIG. 3, it is understood that other numbers of subgrid positions may be used to enhance a numerical solution. For example, there may be a subgrid position located in between each set of four adjacent points 312 along the mesh 310 or alternating along every other set of four adjacent points 312 along the mesh 310. Additionally or alternatively, in some embodiments more than one subgrid position may be located between each set of adjacent four points 312 along the mesh 310. Still further, in some embodiments, one or more of the subgrid positions may not be centered between adjacent points 312 along the mesh 310. In such embodiments, calculating an interpolation for the subgrid position may include calculating a weighted average (e.g., as opposed to a simple mean) of values from adjacent points 312 based on the comparative distance to the adjacent points 312.

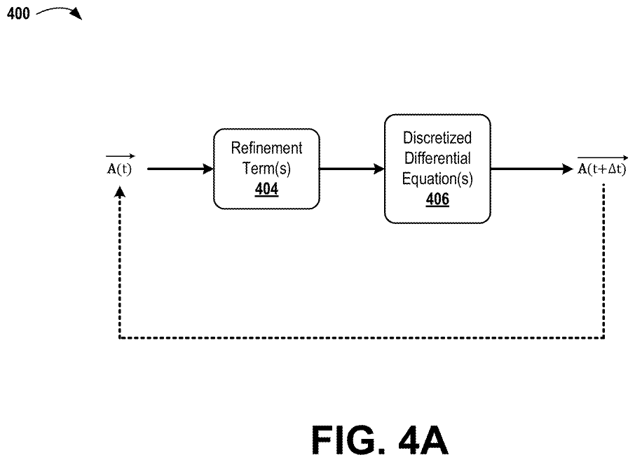

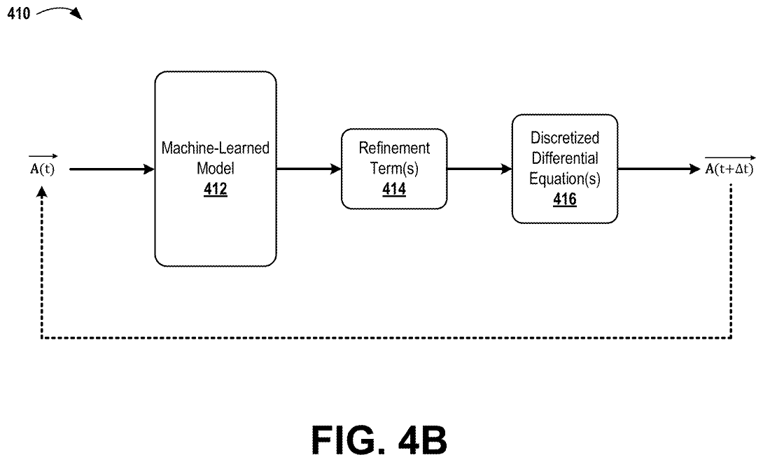

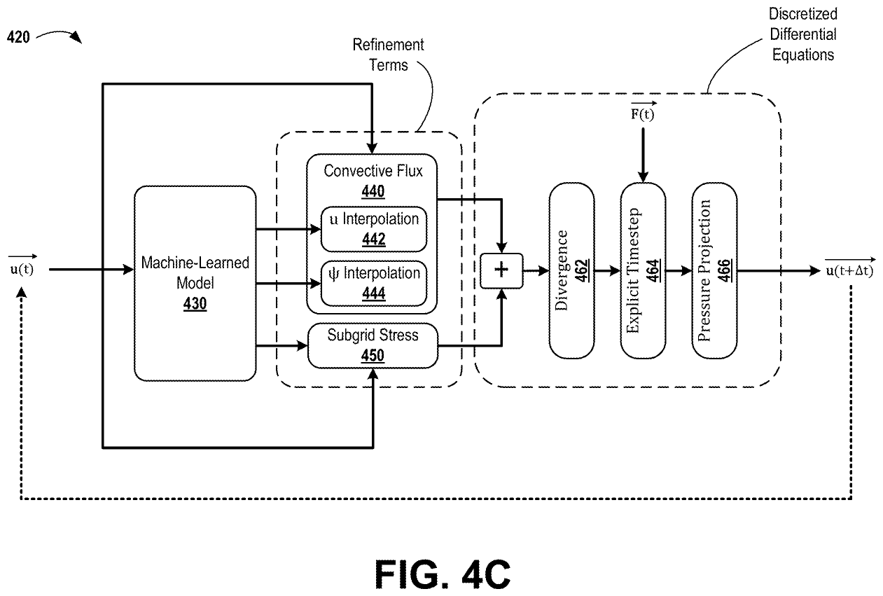

FIG. 4A is a flowchart illustration of a method 400 of refining a numerical simulation by interpolation, according to example embodiments. Such a method may be similar to and/or include the interpolation using subgrid positions 322 described above. As illustrated, the method 400 may include receiving a first vector field (A̅(̅t̅)̅) (e.g., at a first time step, t). Next, the first vector field A̅(̅t̅)̅ may be used to determine refinement terms 404. The refinement terms 404 may be determined using one or more heuristics, as described above (e.g., by plugging values from points within the first vector field A̅(̅t̅)̅ into one or more a priori polynomials that describe the physical system being modeled by the numerical simulation and determining interpolations using those polynomials).

Thereafter, the refinement terms may be used to solve one or more discretized differential equations (e.g., as part of a subsequent iteration of a numerical simulation method, such as a finite difference method or a finite volume method), which may result in a second vector field (A̅(̅t̅+̅Δ̅t̅)̅) (e.g., at a second time step, t+Δt). As indicated by the dashed line, in some embodiments, this second vector field may be fed back to the beginning of the method 400 and the method 400 may be repeated using the second vector field (e.g., in order to ultimately determine a third vector field at a third time step A̅(̅t̅+̅2̅Δ̅t̅)̅).

The technique illustrated in FIG. 4A may require less computational resources for a given accuracy level or have a greater accuracy level for a given amount of computational resources than a traditional direct numerical simulation that does not include refinement terms. However, this technique may be further optimized (e.g., especially for sparsely populated simulation meshes), either in terms of additional accuracy for a given amount of computational resources used or in terms of reduced computational resources required for a given level of accuracy, by using machine learning to assist in determining the one or more refinement terms 404.

FIG. 4B is a flowchart illustration of a method 410 of refining a numerical simulation by interpolation using a machine-learned model 412, according to example embodiments. As illustrated, the method 410 of FIG. 4B may be similar to the method 400 of FIG. 4A, with the exception that the method 410 of FIG. 4B includes the machine-learned model 412. The machine-learned model 412 may include an artificial neural network (e.g., a convolutional neural network, a recurrent neural network, a Bayesian network, a hidden Markov model, a Markov decision process, a logistic regression function, a suitable statistical machine-learning algorithm, and/or a heuristic machine-learning system), a support vector machine, a regression tree, an ensemble of regression trees (also referred to as a regression forest), a decision tree, or an ensemble of decision trees (also referred to as a decision forest), in various embodiments. Other machine-learned structures may also be included and are contemplated herein.

As illustrated in FIG. 4B, the machine-learned model 412 may receive a first vector field (A̅(̅t̅)̅) (e.g., at a first time step, t). Then, based on the first vector field A(t), the machine-learned model 412 may determine one or more refinement terms 414. The refinement terms may include one or more interpolations between points of the first vector field A(t) and/or other values that could be used to enhance the accuracy of the numerical simulation. Determining the refinement terms 414 may include using the machine-learned model 412 to perform interpolations between points in the first vector field A(t). For example, the interpolations may be performed by determining coefficients for one or more polynomials representing the physical system being solved for and then plugging in subgrid positions into those polynomials to evaluate values at those subgrid positions. However, unlike that polynomials that may be used to determine the refinement term(s) 404 of FIG. 4A, the polynomials being determined and/or evaluated using the machine-learned model 412 of FIG. 4B may include many more terms (e.g., hundreds or thousands or terms), as the polynomials used in FIG. 4B may be machine-learned as opposed to analytically generated by hand (e.g., using pen and paper computations). Further, the polynomials used in the method 410 of FIG. 4B may incorporate small-scale variation that is based on training data used to train the machine-learned model 412 that is not contained in an a priori polynomial used in the method 400 to determine the refinement term(s) 404 (e.g., because the polynomial used in the method 400 is used across the entire simulation domain, whereas the polynomials used in the method 410 of FIG. 4B may be localized to different regions of the simulation and different polynomials may be used for different regions of the simulation).

Next, similar to the method 400 illustrated in FIG. 4A, the refinement term(s) 414 may be used to solve one or more discretized differential equations (e.g., as part of a subsequent iteration of a numerical simulation, such as a finite difference method or a finite volume method), which may result in a second vector field (A̅(̅t̅+̅Δ̅t̅)̅) (e.g., at a second time step, t+Δt). Also like FIG. 4A, as indicated by the dashed line, in some embodiments, this second vector field may be fed back to the beginning of the method 410 and the method 410 may be repeated using the second vector field (e.g., in order to ultimately determine a third vector field at a third time step A̅(̅t̅+̅2̅Δ̅t̅)̅).

The machine-learned model 412 may be trained (e.g., during a training phase 102, as illustrated in FIG. 1) to determine the refinement term(s) 414 based on an input vector field (e.g., based on a series of points having associated values that represent a numerical simulation of a physical system). The machine-learned model 412 may be trained in a variety of ways (e.g., depending on the available training data, the type of machine-learned model used, and/or the desired refinement term(s) 414). In some embodiments, the machine-learned model 412 may be trained using training data that includes complete direct numerical solutions (i.e., numerical simulations of similar physical systems that do not employ refinement terms or interpolations) having mesh spacing between points that is denser than the spacing that the machine-learned model 412 will encounter in run-time/during an inference phase of the machine-learned model 412 (e.g., while performing the operations of the method 410 illustrated in FIG. 4B). Such training data may have relatively high numerical accuracy (e.g., and may have taken relatively significant computing resources to generate). Hence, the machine-learned model 412 may encapsulate much of the physical intuition (e.g., at relatively small length scales) that is present within the direct-numerical-simulation training data. Further, because the machine-learned model 412 includes such physical intuition, sparser meshes may be used in the method 410 while still maintaining enhanced accuracy over other methods using a similar density mesh. Said differently, a direct numerical simulation for a given point density along a simulation mesh and a refined numerical simulation for the same point density along the same simulation mesh that does not employ a machine-learned model may each be less representative of the physical system than a numerical simulation for the same point density along the same simulation mesh that does employ the machine-learned model 412 (e.g., using the method 410 illustrated in FIG. 4B).

Additionally, training the machine-learned model 412 (e.g., using complete direct numerical simulations) and/or using the machine-learned model 412 (e.g., to generate new numerical solutions) may include programming the machine-learned model 412 within a differentiable program that can provide direct numerical simulations. Further, the machine-learned model 412 and/or the associated numerical method used to generate the training data (e.g., the direct numerical simulations) may be written in a framework (e.g., using a computer-programming library and associated computer-programming language) that supports reverse-mode automatic differentiation. Using such a framework may permit the machine-learned model 412 to be embedded directly within the numerical simulation method (e.g., during a training phase and/or an inference phase). Because of this, the training process may be optimizable using end-to-end, gradient-based optimization.

In some embodiments, the machine-learned model 412 may be trained according to a training method that minimizes the error between a high-density direct numerical simulation (e.g., the training data) and a numerical simulation of the same system along a coarser mesh using the machine-learned model 412. This may be performed using supervised learning, for example. To perform this supervised learning, a single direct numerical simulation of a high-density mesh may be coarsened (i.e., points may be dropped out, averaged, and/or filtered out to make the mesh more sparse) to the same density being simulated using the machine-learned model 412 and then the results from the simulation of the machine-learned model 412 may be compared to the coarsened representation of the direct numerical simulation. Coarsening the high-density mesh to generate a low-density mesh for training may be performed in a variety of ways, according to example embodiments. For example, the high-density mesh may be coarsened by averaging or subsampling to determine the low-density mesh. This may represent a “box filter” technique so select points along a low-density mesh when associated with large eddy simulation (LES) techniques for turbulent flows. Additionally or alternatively, though, a Gaussian filter or a sharp spectral filter may be used. In other embodiments, a machine-learned technique of generating a low-density mesh from a high-density mesh may be employed. For example, an ANN may be trained to downsample from a high-density mesh to a low-density mesh. This may be done in the form of an encoder/decoder (i.e., autoencoder) model. Additionally, in some embodiments (e.g., employing a trained ANN), a low-density mesh may be enhanced/upsampled to assist in training the ANN used to generate the low-density meshes by downsampling. For example, interpolated points may be added to a low-density mesh and the composite of the low-density mesh and the interpolated points may be used to train the ANN with respect to how to downsample to generate lower-density meshes. Using such a technique to train the downsampling ANN may ensure that the downsampling ANN does not lose details associated with the underlying physical systems when performing the downsampling. Downsampling machine-learned models used to generate training data may be trained prior to, along with, and/or based on the resulting machine-learned model 412, in various embodiments.

Further, minimizing the error within the training method may be represented by minimizing the cumulative pointwise error between the simulation of the machine-learned model 412 (ν̅(tᵢ) below) and the corsened representation of the direct numerical simulation (ν(tᵢ) below). This may correspond to minimizing the following equation (where MSE represents the mean squared error and t represents each time step for the simulations):

$$L ( x , y ) = {\sum }_{{t}_{i}}^{{t}_{T}} M S E ( v ( {t}_{i} ) , \tilde{v} ( {t}_{i} ) )$$

The method 410 illustrated in FIG. 4B is broadly applicable across a range of numerical simulation methodologies (e.g., finite difference method, finite volume method, finite element method, the method of moments, etc.). Further, the method 410 may also be employed across a variety of physical systems (e.g., electromagnetic, heat, turbulent flow, etc.) described by a variety of different differential equations (e.g., Maxwell's equations, the heat equation, Navier-Stokes equation, etc.). It is understood that each of the above is contemplated herein. However, as an example, FIG. 4C illustrates embodiments used to refine simulation results for a turbulent flow (e.g., a finite volume method simulation of a turbulent flow, such as the turbulent flow illustrated in FIG. 3).

FIG. 4C is a flowchart illustration of a method 420 of refining a numerical simulation of a turbulent flow by interpolation using a machine-learned model 430, according to example embodiments. The method 420 of FIG. 4C may be used to simulate Navier-Stokes equations using the finite volume method employing the marker-and-cell model, for example. The Navier-Stokes equations are partial differential equations that describe the flow of fluids. One form of the Navier-Stokes equations for turbulent flows in an incompressible fluid incorporates the following two equations (sometimes referred to as the convective form of the incompressible Navier-Stokes equations):

$$\frac{\partial {u}^{*}}{\partial {t}^{*}} + {∇}^{*} \cdot ( {u}^{*} ⊗ {u}^{*} ) = v {Δ}^{*} {u}^{*} - \frac{1}{ρ} {∇}^{*} {p}^{*} + {f}^{*}$$

$$∇ \cdot u = 0$$

Where u* is velocity field, p is the fluid density, ν is the kinematic viscosity, and f * is the external forcing field. The first equation above can be rewritten in the following non-dimensionalized form by selecting the appropriate lengthscale (e.g., based on the characteristic lengthscale of the flow L) and choice of units:

$$\frac{\partial u}{\partial t} + ∇ \cdot ( u ⊗ u ) = \frac{1}{R e} Δ u - \frac{1}{ρ} ∇ p + \frac{1}{F {r}^{2}} f$$

$$where R e = \frac{U L}{v} and Fr = \frac{U}{\sqrt{F L}}$$

are dimensionless Reynolds and Froude numbers, respectively, that fully parameterize the nature of the flow. The Froude number represents the ratio between inertial flow and external forcing, whereas the Reynolds number represents the complexity of the flow, which can be linked to the size of the smallest turbulent lengthscale η, known as the Kolmogorov scale. The Kolmogorov scale determines the size of elementary degrees of freedom in the problem and decreases with increasing complexity of the flow.

In some techniques that can be used to simulate turbulent flows using Navier-Stokes equations, there may be an underlying assumption that convection dominates (e.g., over diffusion). Additionally or alternatively, some simulation techniques may involve explicitly solving for the convective flux (e.g., using explicit time-stepping), while implicitly solving for pressure and diffusion. This may be referred to as the explicit convective flux model. In some embodiments, the explicit convective flux model may be used over other techniques because the convective flux term in the Navier-Stokes equations is non-linear, which makes performing implicit time-stepping more complicated to implement and/or more computationally intense. The explicit convective flux model can be used in conjunction with the finite volume method (e.g., and, additionally, the marker-and-cell method) to generate numerical simulations of turbulent flow systems. The method 420 illustrated in FIG. 4C makes use of the explicit convective flux model. It is understood, however, that other models for turbulent flow could equally be used with appropriate modifications to the method 420.

When performing a direct numerical simulation to solve Navier-Stokes equations, the simulation will converge to the exact solution when the Kolmogorov scale η is fully resolved on the mesh (i.e., when the mesh has separations smaller than the Kolmogorov scale η). However, performing direct numerical simulations at such lengthscales may be computationally expensive. If numerical simulations are performed at lengthscales greater than the Kolmogorov scale η, though, loss in accuracy (e.g., due to numerical approximations and/or missing subgrid features) may occur as a result of a breakdown of an underlying assumption about a smoothness of the solution to the differential equations. Hence, the technique employing a machine-learned model 430 illustrated in FIG. 4C allows for less-dense meshes to be used to reduce computation expense without losing all of the accuracy of a more-dense mesh used with a direct numerical simulation.

A technique for refining solutions associated with coarser grids may include incorporating a residual stress term into the Navier-Stokes equations and then solving the Navier-Stokes equations with this additional term. Such a revised Navier-Stokes equation may take the following form:

$$\frac{\partial \overline{u}}{\partial t} + ∇ \cdot ( \overline{u} ⊗ \overline{u} ) + ∇ \cdot {\underbrace{( \overline{u ⊗ u} - \overline{u} ⊗ \overline{u} )}}_{Residual stress} = \frac{1}{R e} Δ \overline{u} - \frac{1}{ρ} ∇ \overline{p} + f$$

The residual stress term above may be modeled as a closure term, in some embodiments. Additionally, as indicated by the equation above, the residual stress term may be modeled as depending purely on ū and its derivatives. The above equation and representation of the residual stress term may be used, for example, in LES techniques and in Reynolds-averaged Navier-Stokes (RANS) techniques. It is understood that other residual stress terms are also possible and are contemplated herein.

In some embodiments, the residual stress term above may have expected scaling laws (e.g., polynomial scaling). This may be due to an a priori approximation developed based on physical intuition from the differential equations themselves and/or, when employing a machine-learned model such as the machine-learned model 430 of FIG. 4C, based on information contained in the training data used to train the machine-learned model. Some example residual stress terms may be described by eddy viscosity models that parametrize a residual stress tensor τ_{i,j} as:

$${τ}_{i j} = - 2 {v}_{i j} ∘ {\overline{S}}_{i j} {S}_{i j} = \frac{1}{2} ( {\partial }_{i} {u}_{j} - {\partial }_{j} {u}_{i} )$$

where ν_{i,j} is the eddy viscosity tensor and S_{i,j} is the strain rate tensor. The eddy viscosity tensor may be flow-dependent and, therefore, different for different regions of the simulation domain. A commonly used analytical (i.e., not machine-learned) example of an eddy viscosity tensor is the Smagorinsky-Lilly model:

ν=(Cₛh)²\sqrt{2S_{i,j}S_{i,j}}

where h is the size of the grid and Ci s is a constant.

As illustrated in FIG. 4C, and similar to the method 410 of FIG. 4B, the method 420 may include providing a first vector field (e.g., the velocity field u̅(̅t̅)̅ of the Navier-Stokes equations described above at a first time step, t) to the machine-learned model 430 (e.g., an artificial neural network). The machine-learned model 430 may then use the first vector field to determine refinement terms. The refinement terms may include refinement terms for the convective flux 440 (e.g., an advecting velocity (u) interpolation 442 and an advected velocity (Ψ) interpolation 444), as well as a subgrid stress 450 (e.g., a subgrid stress tensor). The interpolations 442, 444 may correspond to the velocity components at subgrid positions (e.g., similar to the subgrid position 322 illustrated and described with reference to FIG. 3). Additionally, the subgrid stress 450 may correspond to the residual stress term imported into the Navier-Stokes equations for less-dense meshes, as described above. In some embodiments, a subgrid stress tensor may be evaluated at one or more subgrid locations, hence the nomenclature. Each of these elements (the advecting velocity (u) interpolation 442, the advected velocity (Ψ) interpolation 444, and the subgrid stress 450) may be represented by more or more tensors (e.g., one or more matrices).

In some embodiments, the machine-learned model 430 may determine the interpolations 442, 444 and the subgrid stress 450 during an inference phase based on training (e.g., training performed during a training phase) based on training data. As indicated above, the training data may be generated from direct numerical simulations, such as coarsened versions of high-density direct numerical simulations. In some embodiments, the training data used to train the machine-learned model 430 may broadly relate to numerical simulations of differential equations that describe physical phenomena. Additionally, in some embodiments, the training data may specifically relate to turbulent flows and/or, even more specifically, Navier-Stokes equations. For example, the training data may include direct numerical simulations, such as coarsened versions of high-density direct numerical simulations, for well-characterized turbulent flows, such as decaying turbulence or the Kolmogorov flow. The Kolmogorov flow in two-dimensions can be described using the following forcing field equation, for example:

f=sin(4y)\hat{x}−0.1u

where the second term above corresponds to a velocity-dependent drag that prevents accumulation of energy at large scales caused by the inverse energy cascade of two-dimensional turbulence. When the above forcing field is removed (after being enforced for some non-zero time), the system will undergo a transition period during which small-scale structures coalesce to form large-scale structures. This transition process represents a decaying turbulence. Additionally or alternatively, in some embodiments, the training data may include large eddy simulations or Reynolds-averaged Navier-Stokes simulations.

Similar to the methods 400, 410 of FIGS. 4A and 4B, respectively, after determining the refinement terms 442, 444, 450, the method 420 of FIG. 4C may use the refinement terms 442, 444, 450 to solve a system of discretized differential equations and produce a second vector field at a second time step (e.g., velocity field u̅(̅t̅+̅Δ̅t̅)̅ of the Navier-Stokes equations at a second time step, t+Δt). In the Navier-Stokes simulation of turbulent flow provided in FIG. 4C, solving the system of discretized differential equations may include incorporating the influence of the refinement terms 442, 444, 450 into the simulation (represented by the +sign in FIG. 4C), computing a divergence 462 of the revised velocity field u̅(̅t̅)̅, applying the forcing field at the first time step F̅(̅t̅)̅, advancing an explicit timestep 464 (e.g., to t+Δt), and determining the pressure projection 466 to arrive at the second velocity field u̅(̅t̅+̅Δ̅t̅)̅ of the Navier-Stokes equations at the second time step (t+Δt). In other embodiments, additional or alternative methodologies for solving the system of discretized differential equations may be used. Also similar to the methods 400, 410 illustrated in FIGS. 4A and 4B, the method 420 of FIG. 4C may include, as indicated by the dashed line, feeding the second vector field u̅(̅t̅+̅Δ̅t̅)̅ back to the beginning of the method 420 and repeating the method 420 using the second vector field u̅(̅t̅+̅Δ̅t̅)̅ (e.g., in order to ultimately determine a third vector field at a third time step u̅(̅t̅+̅Δ̅t̅)̅).

While it is described throughout this disclosure that the refinement terms may be used to determine a consequential vector field at a different timestep (e.g., velocity field u̅(̅t̅+̅Δ̅t̅)̅ of the Navier-Stokes equations at the second time step, t+Δt), it is understood that this is provided merely as an example. In other embodiments, the refinement terms could also be used to refine the numerical simulation at the first time step. Similarly, the numerical simulation may not be a time-evolving simulation (e.g., may be a static simulation or a simulation relating to a steady-state system). In such cases, the refinement terms may be used to enhance the accuracy of the static simulation (e.g., when a low-density mesh is being used to simulate standing electromagnetic waves within a waveguide) without regard to time steps at all. For example, steady-state simulations may be solved iteratively, where each iteration represents a refined determination of the solution. Some RANS numerical simulations may be performed this way, for instance. In such steady-state embodiments, the techniques described herein may be used to determine refinements between each iteration.

Many of the operations illustrated in FIG. 4C involve multiplying tensors (e.g., matrices) with one another. For example, taking inner products and/or cross products to solve discretized differential equations and/or determining the refinement terms 442, 444, 450 using the machine-learned model 430 (e.g., as a result of deep learning) may rely on tensor multiplication. Additionally, in some embodiments, one or more of the tensors used may be relatively sparse. As such, many of the tensor entries may be ignored and/or the tensors may be broken down into smaller representations and then recombined to form a complete tensor after the multiplication has been performed. Based on the computations involved and described herein, the operations in FIG. 4C may experience further enhancement than traditional direct numerical simulations when performed by one or more specially designed computing devices (e.g., processors), such as TPUs or GPUs.

As described above, the machine-learned model 430 may be used to determine the convective flux 440 (e.g., including the advecting velocity (u) interpolation 442 and the advected velocity (Ψ) interpolation 444) and/or the subgrid stress 450. Determining the subgrid stress 450 and determining the convective flux 440 using the machine-learned model 430 will each be described, in turn, below.

As described above, the subgrid stress 450 may be represented by a subgrid stress tensor T_{i,j}. As illustrated in FIG. 4C, in some embodiments, the machine-learned model 430 (e.g., an artificial neural network) may determine a subgrid stress tensor τ_{i,j} based on the first vector field at the first time step u̅(̅t̅)̅. This is augments the heuristic, analytical description of the subgrid stress tensor τ_{i,j} disclosed above (e.g., the subgrid stress tensor τ_{i,j} of FIG. 4C is determined based on the machine-learned model 430 and not solely an a priori analytical equation).

Determining the subgrid stress tensor r (e.g., using the machine-learned model 430) may include, as described above, determining an eddy viscosity term. In example embodiments described herein, different forms of the eddy viscosity term may be generated using the machine-learned model 430. For example, the eddy viscosity term may be a scalar eddy viscosity term in the following subgrid stress tensor Y u equation:

τ_{i,j}^{ev}=−2ν_{sgs}S̅_{i,j}

where τ_{i,j} represents the subgrid stress tensor, ν_{sgs}, represents the scalar eddy viscosity at the points along the mesh, and S_{i,j} represents the strain rate tensor (e.g., the strain rate tensor S_{i,j} described above). In embodiments using the scalar eddy viscosity model, determining the eddy viscosity term (and, consequently, the subgrid stress tensor τ_{i,j}) may include predicting, using the machine-learned model 430, eddy viscosities for each of the plurality of points along the mesh of the numerical simulation (e.g., determine ν_{sgs}, at each point along the mesh). Further, determining the eddy viscosity term in embodiments using the scalar eddy viscosity model may include calculating the strain rate tensor S_{i,j} based on the first vector field u̅(̅t̅)̅ and the mesh. In addition, determining the eddy viscosity term in embodiments using the scalar eddy viscosity model may include interpolating one or more of the eddy viscosities to one or more subgrid positions using the calculated strain rate tensor S_{i,j}.

In other embodiments, the eddy viscosity term may be generated using the machine-learned model 430 using a tensor eddy viscosity model ν_{i,j}. In such embodiments, determining the tensor eddy viscosity v u (and, subsequently, determining the subgrid stress tensor τ_{i,j}) may include predicting, using the machine-learned model 430, eddy viscosities for each of the one or more subgrid positions. In other words, rather than using the machine-learned model 430 to determine the eddy viscosities at grid points and then interpolating to find subgrid eddy viscosities (as in the scalar eddy viscosity model described above), the machine-learned model 430 may be used to directly produce a tensor eddy viscosity ν_{i,j} for subgrid positions.

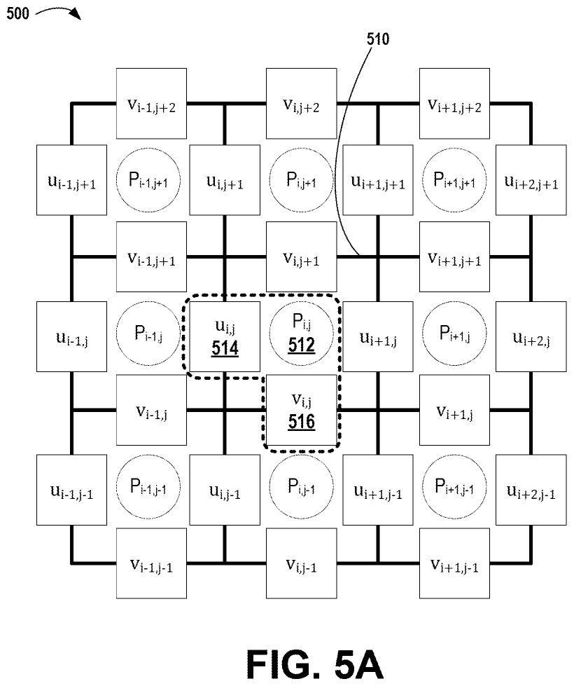

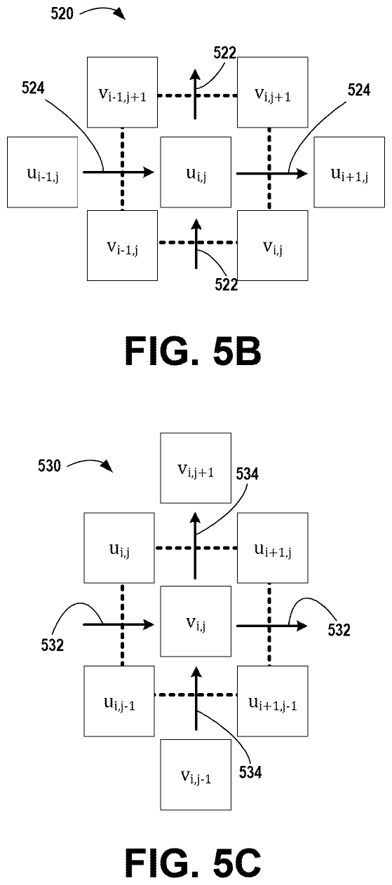

As illustrated in FIG. 4C, in addition to determining the subgrid stress 450 using the machine-learned model 430, the method 420 may include using the machine-learned model 430 to determine the convective flux 440 for the Navier-Stokes equations based on the advecting velocity (u) interpolation 442 and the advected velocity OP) interpolation 444, which represent the components of convective flux at subgrid positions (e.g., between points along the mesh of the numerical simulation). The convective flux interpolation may be performed based on the type of numerical simulation method and/or discretization method used. As an example, the finite volume method employing a marker-and-cell discretization will be described below with reference to FIGS. 5A-5C. It is understood that other simulation methods (e.g., finite difference method and finite element method), as well as other discretization methods are also possible and are contemplated herein.

FIG. 5A is a marker-and-cell method 500 used in an interpolation (e.g., the convective flux 440 interpolation of the method 420 of FIG. 4C), according to example embodiments. While a two-dimensional representation using the marker-and-cell method is illustrated in FIG. 5A, it is understood that a similar approach may be used for three-dimensional cells in a three-dimensional simulation. In the marker-and-cell method 500, as applied to Navier-Stokes equations and, particularly, as applied to convective flux calculations, the system is discretized as a series of cells 510 (e.g., finite volumes along a mesh). By convention in the marker-and-cell method 500, pressures 512 within the Navier-Stokes equations are defined at the centers of each of the cells. For example, the pressure 512 at the cell 510 having coordinates (i, j) is encapsulated by the dashed box in FIG. 5A. Similarly by convention in the marker-and-cell method 500, the horizontal components 514 of the velocity field and the vertical components 516 of the velocity field are defined at the faces of the cells 510 (e.g., the horizontal components 514 of the velocity field are defined on the left faces of the cells 510 and the vertical components 516 of the velocity field are defined on the bottom faces of the cells 510). For example, the horizontal component 514 of the velocity field and the vertical component 516 of the velocity field at the cell 510 having coordinates (i, j) are also encapsulated by the dashed box in FIG. 5A. Also by convention and as illustrated in Figure the horizontal components 514 and vertical components 516 of the velocity field for a given cell 510 may be defined along the negative-facing faces of the cell 510. For example, the horizontal component 514 of the velocity field of the cell 510 having coordinates (i, j) may be on the face between the cell 510 having coordinates (i-1, j) and the cell 510 having coordinates (i, j) (e.g., on the left face of the (i, j) cell, with positive horizontal velocities being to the right). Similarly, the vertical component 516 of the velocity field of the cell 510 having coordinates (i, j) may be on the face between the cell 510 having coordinates (i, j-1) and the cell 510 having coordinates (i, j) (e.g., on the bottom face of the (i, j) cell, with positive vertical velocities being upward). It is understood that other conventions may be used to define velocity components and pressures and are contemplated herein.

Determining the convective flux 440 for the Navier-Stokes equations based on the an advecting velocity (u) interpolation 442 and the advected velocity (0) interpolation 444 using the machine-learned model 430 may include determining the horizontal velocity component 514 and vertical velocity component 516 (or a single velocity component in a one-dimensional simulation or three velocity components in a three-dimensional simulation) at one or more faces of the cell 510 on the grid (e.g., for one or more subgrid positions corresponding to the position of the faces of the cell 510). Determining the advecting velocity (u) interpolation 442 using the machine-learned model 430 may correspond to determining a first velocity component of the cell 510 within the first vector field u(t), whereas determining the advected velocity (0) interpolation 444 using the machine-learned model 430 may correspond to determining a movement of the first vector field u(t) as a whole. Determining the advecting velocity (u) interpolation 442 using the machine-learned model 430 may be done by interpolating based on velocity components of points along the mesh within the first vector field u(t), for example. Determining the advected velocity (0) interpolation 444 using the machine-learned model 430, however, may correspond to determining components of the first vector field u(t) that are perpendicular to a respective face of the respective cell 510.

As described above, using the machine-learned model 430 to determine the convective flux 440 at a given finite volume (e.g., given cell 510) may include performing interpolations to determine velocities (e.g., horizontal velocity components 514 and vertical velocity components 516) at different subgrid positions. Such interpolations are depicted in FIGS. 5B and 5C.

As illustrated in the interpolation 520 of FIG. 5B, the two subgrid vertical velocity components 522 and the two subgrid horizontal velocity components 524 (e.g., as evaluated at the left face of every cell 510 where u_{i,j} is defined) may be determined based on interpolations. For example, the subgrid vertical velocity components 522 for u_{i,j} may be determined (e.g., using a simple average) between vᵢ₋₁ⱼ₊₁ and v_{i,j+1} for the top face and between vᵢ₋₁ⱼ and vi for the bottom face. Likewise, the subgrid horizontal velocity components 524 for u_{i,j} may be determined (e.g., using a simple average) between uᵢ₋₁ⱼ and u_{i,j} for the left face and between u, and tᵢ₊₁ⱼ for the right face.

Similarly for the interpolation 530 of FIG. 5C, the two subgrid horizontal velocity components 532 and the two subgrid vertical velocity components 534 (e.g., as evaluated at the bottom face of every cell 510 where v_{i,j} is defined) may be determined based on interpolations. For example, the subgrid horizontal velocity components 532 for v_{i,j} may be determined (e.g., using a simple average) between u_{i,j} and u_{i,j-1} for the left face and between t_{i+1,j} and u_{i+1,j-1} for the right face. Likewise, the subgrid vertical velocity components 534 for vi may be determined (e.g., using a simple average) between v_{i,j+1} and v_{i,j} for the top face and v_{i,j} and v_{i,j-1} for the bottom face.

Using all the above-referenced interpolations, the relevant horizontal and vertical components of velocity can be determined at each face of the cell 510. Then, using the horizontal and vertical components of velocity, the convective flux of the grid cells 510 may be determined. As such, it may be said that the convective flux 440 is interpolated by the machine-learned model 430. While these interpolations may be performed as a way to discretize the numerical simulation, additional cells may be defined (e.g., in subgrid regions beyond grid cells 510 purely defined on the mesh that only have subgrid faces). In some embodiments, it may be these subgrid cells (with subgrid centers and subgrid faces, as opposed to merely just subgrid faces) for which the machine-learned model 430 may be used to determine interpolations of convective flux 440, as illustrated in FIG. 4C. To do this, the machine-learned model 430 may be used to interpolate between points (e.g., grid cells 510) on the mesh by: determining one or more coefficients for a polynomial (e.g., a machine-learned polynomial, such as a machine-learned polynomial having many terms, such as hundreds or thousands of terms) and evaluating the polynomial based on the one or more determined coefficients and the values of the first vector field u(t) at given points (e.g., grid cells 510) along the mesh. In some embodiments, the polynomial used may correspond to a localized stencil for the nearby points (e.g., grid cells 510) along the mesh. Using the machine-learned model 430 to predict coefficients for the polynomial rather than to predict the interpolated values with no polynomial stencil may ensure that the machine-learned model 430 most accurately reflects the physical system by building in physical intuition into the model. However, in other embodiments, the machine-learned model 430 may be used to directly predict the interpolated values (e.g., without a polynomial stencil).

### III. Example Processes

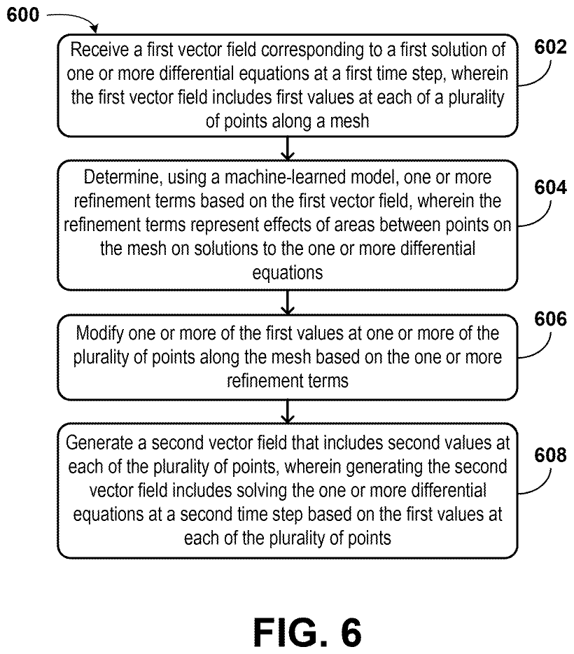

FIG. 6 is a flowchart diagram of a method 600, according to example embodiments. In some embodiments, the method 600 may be a computer-implemented method for performing enhanced numerical simulations. The method 600 may be performed to implement the method 410 illustrated in FIG. 4B, for example. In some embodiments, the method 600 may be performed by one or more processors of a system executing instructions stored in a non-transitory, computer-readable medium. The one or more processors may include one or more GPUs or one or more TPUs, for example. Similarly, the method 600 may be performed by a computing device executing instructions stored within a non-transitory, computer-readable medium of an article of manufacture.

At block 602, the method 600 may include receiving a first vector field corresponding to a first solution of one or more differential equations at a first time step. The first vector field includes first values at each of a plurality of points along a mesh.

At block 604, the method 600 may include determining, using a machine-learned model, one or more refinement terms based on the vector field. The refinement terms represent effects of areas between points on the mesh on solutions to the one or more differential equations.

At block 606, the method 600 may include modifying one or more of the first values at one or more of the plurality of points along the mesh based on the one or more refinement terms.

At block 608, the method 600 may include generating a second vector field that includes second values at each of the plurality of points. Generating the second vector field may include solving the one or more differential equations at a second time step based on the first values at each of the plurality of points.

In some embodiments of the method 600, the plurality of points along the mesh, the first vector field, the first time step, the second vector field, and/or the second time step may be discretized according to a finite difference method or a finite volume method.

In some embodiments of the method 600, the plurality of points along the mesh, the first vector field, the first time step, the second vector field, and/or the second time step may be discretized according to a finite element method.

In some embodiments of the method 600, the one or more differential equations may include one or more partial differential equations. Further, the one or more differential equations may represent turbulent flow within a fluid.

In some embodiments of the method 600, the one or more differential equations may include one or more Navier-Stokes equations.

In some embodiments of the method 600, block 604 may include determining a subgrid stress tensor.

Additionally, in some embodiments of the method 600, determining the subgrid stress tensor may include using the machine-learned model to determine an eddy viscosity term.

Further, in some embodiments of the method 600, the subgrid stress tensor may be determined using a scalar eddy viscosity model. Still further, determining the subgrid stress tensor may include: (i) predicting, using the machine-learned model, eddy viscosities for each of the plurality of points along the mesh; (ii) calculating a strain rate tensor based on the first vector field and the mesh; and (iii) interpolating one or more of the eddy viscosities to one or more subgrid positions using the calculated strain rate tensor.

In addition, in some embodiments of the method 600, the subgrid stress tensor may be determined using a tensor eddy viscosity model. Still further, determining the subgrid stress tensor may include predicting, using the machine-learned model, eddy viscosities for each of one or more subgrid positions.

In some embodiments of the method 600, the one or more refinement terms may include one or more convective flux components interpolated between points on the mesh.

Additionally, in some embodiments of the method 600, interpolating between points on the mesh may include: (i) determining, using the machine-learned model, a first velocity component for each face of a grid cell corresponding to a subgrid position and (ii) determining, using the machine-learned model, a second velocity component across each face of the grid cell. The first velocity components may represent a movement of the grid cell within the first vector field. The grid cell may be defined according to a marker-and-cell method. The second velocity components may correspond to components of the first vector field perpendicular to a respective face of the grid cell. The second velocity components may represent a movement of the first vector field as a whole.

In some embodiments of the method 600, interpolating between points on the mesh may include: (i) determining, using the machine-learned model, one or more coefficients for a polynomial and (ii) evaluating the polynomial based on the one or more determined coefficients and first values of the first vector field at nearby points along the mesh.

Yet further, in some embodiments of the method 600, the polynomial may correspond to a localized stencil for the nearby points along the mesh.

In some embodiments of the method 600, the machine-learned model may include an artificial neural network.

In some embodiments of the method 600, the machine-learned model may be trained using solutions generated by direct numerical simulations, large eddy simulations, and/or Reynolds-averaged Navier-Stokes simulations.

In some embodiments of the method 600, the machine-learned model may be trained using solutions generated for Kolmogorov flows and/or decaying turbulence flows.

In some embodiments of the method 600, the machine-learned model may be trained using coarsened versions of solutions generated by direct numerical simulations. The coarsened versions may be generated by: averaging points of the solutions generated by the direct numerical simulations; subsampling points of the solutions generated by the direct numerical simulations according to a box filter, a Gaussian filter, or a sharp spectral filter; or using an additional machine-learned model.

In some embodiments of the method 600, the one or more differential equations may describe electromagnetic fields, electromagnetic forces, electromagnetic potential, and/or electric charges.

In some embodiments of the method 600, the one or more differential equations may include one or more of Maxwell's equations.

### IV. Experimental Results

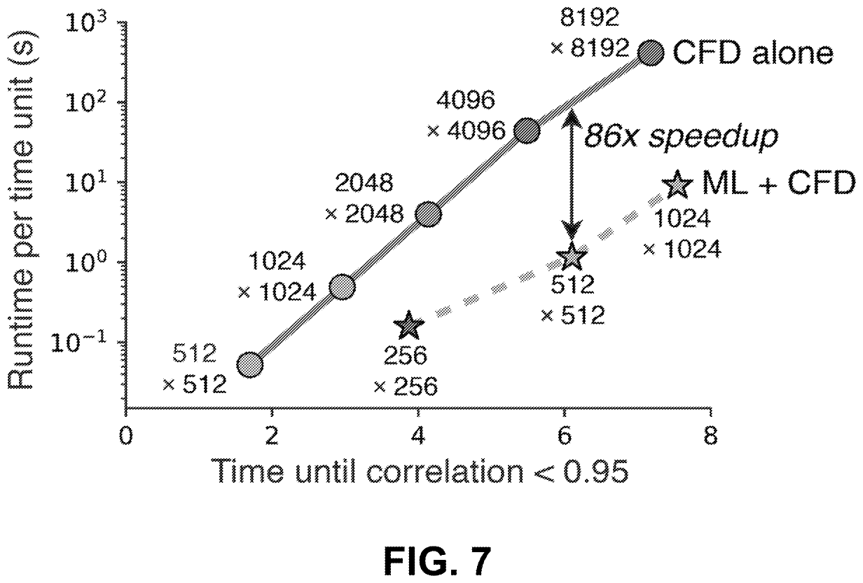

FIG. 7 illustrates the accuracy versus computational cost using a baseline computational fluid dynamics (CFD) solver to the techniques described herein (ML+CFD). In FIG. 7, the x axis corresponds to pointwise accuracy, showing how long the simulation is highly correlated with the ground truth, whereas the y-axis shows the computational time needed to carry out one simulation time-unit on a single TPU core (e.g., a single core of the Cloud TPU v4 produced by GOOGLE). Each point in FIG. 7 is annotated by the size of the corresponding grid. As outlined in FIG. 7, for a two dimensional direct numerical simulation of a turbulent flow, our algorithm maintains accuracy while using 10 times coarser resolution in each dimension, resulting in a 86 fold improvement in computational time with respect to an advanced numerical method of similar accuracy. The techniques described herein include models that learn how to interpolate local features of solutions and, hence, can accurately generalize to different flow conditions, such as different forcings and even different Reynolds numbers.

Further, when the techniques described herein are applied to a high-resolution LES simulation of a turbulent flow, similar performance enhancement to this described with respect to FIG. 7 can be achieved. For example, for an LES having an Re=100,000, techniques described herein showed a 100-fold computational speedup with ˜10 times coarser grid compared to conventional LES simulations.

In evaluating the techniques described herein, accuracy, computational efficiency, and generalization must all be considered. Generalization means the amount that, although the machine-learned model may be trained on a specific solution set (e.g., a specific flow in the case of fluid dynamics), the machine-learned model can be proficiently used in new simulations (e.g., with different forcings and/or different Reynolds numbers).

Accuracy—The accuracy of fluid dynamic simulations can be quantified by correlating vorticity fields C(ω̅, ω) between the ground truth solution ω and the predicted state co. Experimentally, it was found that the learned discretization technique described herein matches the pointwise accuracy of DNS with a ˜10 times coarser grid. For example, a fully resolved DNS of Kolmogorov flow (2048² mesh, considered to represent ground truth) was more accurately represented using the techniques described herein with a 64² grid than a DNS using a 512² grid.

Computational Efficiency—The ability for the techniques described herein to match DNS with ˜10 times coarser grid makes the learned discretization solver much faster. To perform benchmarking, a single core of the Cloud TPU v4 produced by GOOGLE (a hardware accelerator designed for accelerating machine-learning models that is also suitable for general purpose scientific simulations) was used. This TPU is designed for high throughput vectorized operations and extremely high throughput matrix-matrix multiplication in low precision (e.g., bfloat16), which the machine-learned model described herein can make efficient use of. For reference, the techniques described herein, while being about 20 times slower than a traditional solver at the same resolution, showed a 50 times speedup due to the 10 times gain in effective resolution due to the increase in accuracy.

Generalization—The techniques described herein were tested by being trained on a Kolmogorov flow (Re=1000) and then tested on other flows. For example, the Kolmogorov-flow trained model was tested on a decaying turbulent flow, and demonstrated that the accuracy of a DNS running at ˜7 times the resolution could be matched. Further, the Kolmogorov-flow trained model (Re=1000) was tested on flows with higher Reynolds numbers (Re=4000) to evaluate generalization. Again, the techniques described herein demonstrated that the accuracy of a DNS running at ˜7 times the resolution could be matched.

### V. CONCLUSION

The present disclosure is not to be limited in terms of the particular embodiments described in this application, which are intended as illustrations of various aspects. Many modifications and variations can be made without departing from its spirit and scope, as will be apparent to those skilled in the art. Functionally equivalent methods and apparatuses within the scope of the disclosure, in addition to those enumerated herein, will be apparent to those skilled in the art from the foregoing descriptions. Such modifications and variations are intended to fall within the scope of the appended claims.

The above detailed description describes various features and functions of the disclosed systems, devices, and methods with reference to the accompanying figures. In the figures, similar symbols typically identify similar components, unless context dictates otherwise. The example embodiments described herein and in the figures are not meant to be limiting. Other embodiments can be utilized, and other changes can be made, without departing from the scope of the subject matter presented herein. It will be readily understood that the aspects of the present disclosure, as generally described herein, and illustrated in the figures, can be arranged, substituted, combined, separated, and designed in a wide variety of different configurations, all of which are explicitly contemplated herein.

With respect to any or all of the message flow diagrams, scenarios, and flow charts in the figures and as discussed herein, each step, block, operation, and/or communication can represent a processing of information and/or a transmission of information in accordance with example embodiments. Alternative embodiments are included within the scope of these example embodiments. In these alternative embodiments, for example, operations described as steps, blocks, transmissions, communications, requests, responses, and/or messages can be executed out of order from that shown or discussed, including substantially concurrently or in reverse order, depending on the functionality involved. Further, more or fewer blocks and/or operations can be used with any of the message flow diagrams, scenarios, and flow charts discussed herein, and these message flow diagrams, scenarios, and flow charts can be combined with one another, in part or in whole.

A step, block, or operation that represents a processing of information can correspond to circuitry that can be configured to perform the specific logical functions of a herein-described method or technique. Alternatively or additionally, a step or block that represents a processing of information can correspond to a module, a segment, or a portion of program code (including related data). The program code can include one or more instructions executable by a processor for implementing specific logical operations or actions in the method or technique. The program code and/or related data can be stored on any type of computer-readable medium such as a storage device including RAM, a disk drive, a solid state drive, or another storage medium.

Moreover, a step, block, or operation that represents one or more information transmissions can correspond to information transmissions between software and/or hardware modules in the same physical device. However, other information transmissions can be between software modules and/or hardware modules in different physical devices.

The particular arrangements shown in the figures should not be viewed as limiting. It should be understood that other embodiments can include more or less of each element shown in a given figure. Further, some of the illustrated elements can be combined or omitted. Yet further, an example embodiment can include elements that are not illustrated in the figures.

While various aspects and embodiments have been disclosed herein, other aspects and embodiments will be apparent to those skilled in the art. The various aspects and embodiments disclosed herein are for purposes of illustration and are not intended to be limiting, with the true scope being indicated by the following claims.

1. A computer-implemented method for performing enhanced numerical simulations comprising:
receiving a first vector field corresponding to a first solution of one or more differential equations at a first time step, wherein the first vector field comprises first values at each of a plurality of points along a mesh;
determining, using a machine-learned model, one or more refinement terms based on the first vector field, wherein the refinement terms represent effects of areas between points on the mesh on solutions to the one or more differential equations;
modifying one or more of the first values at one or more of the plurality of points along the mesh based on the one or more refinement terms; and
generating a second vector field comprising second values at each of the plurality of points, wherein generating the second vector field comprises solving the one or more differential equations at a second time step based on the first values at each of the plurality of points.

2. The computer-implemented method of claim 1, wherein the plurality of points along the mesh, the first vector field, the first time step, the second vector field, and the second time step are discretized according to a finite difference method or a finite volume method.

3. The computer-implemented method of claim 1, wherein the plurality of points along the mesh, the first vector field, the first time step, the second vector field, and the second time step are discretized according to a finite element method.

4. The computer-implemented method of claim 1,
wherein the one or more differential equations comprise one or more partial differential equations, wherein the one or more differential equations represent turbulent flow within a fluid, and wherein the one or more differential equations comprise one or more Navier-Stokes equations.

5. (canceled)

6. The computer-implemented method of claim 1,
wherein determining the one or more refinement terms comprises determining a subgrid stress tensor.

7. The computer-implemented method of claim 6, wherein determining the subgrid stress tensor comprises using the machine-learned model to determine an eddy viscosity term.

8. The computer-implemented method of claim 7, wherein the subgrid stress tensor is determined using a scalar eddy viscosity model, and wherein determining the subgrid stress tensor further comprises:
predicting, using the machine-learned model, eddy viscosities for each of the plurality of points along the mesh;
calculating a strain rate tensor based on the first vector field and the mesh; and
interpolating one or more of the eddy viscosities to one or more subgrid positions using the calculated strain rate tensor.

9. The computer-implemented method of claim 7, wherein the subgrid stress tensor is determined using a tensor eddy viscosity model, and wherein determining the subgrid stress tensor further comprises predicting, using the machine-learned model, eddy viscosities for each of one or more subgrid positions.

10. The computer-implemented method of claim 4, wherein the one or more refinement terms comprise one or more convective flux components interpolated between points on the mesh.

11. The computer-implemented method of claim 10, wherein interpolating between points on the mesh comprises:
determining, using the machine-learned model, a first velocity component for each face of a grid cell corresponding to a subgrid position, wherein the first velocity components represent a movement of the grid cell within the first vector field, and wherein the grid cell is defined according to a marker-and-cell method; and
determining, using the machine-learned model, a second velocity component across each face of the grid cell, wherein the second velocity components correspond to components of the first vector field perpendicular to a respective face of the grid cell, and wherein the second velocity components represent a movement of the first vector field as a whole.

12. The computer-implemented method of claim 10,
wherein interpolating between points on the mesh comprises:
determining, using the machine-learned model, one or more coefficients for a polynomial; and
evaluating the polynomial based on the one or more determined coefficients and first values of the first vector field at nearby points along the mesh.

13. The computer-implemented method of claim 12, wherein the polynomial corresponds to a localized stencil for the nearby points along the mesh.

14. The computer-implemented method of claim 1,
wherein the machine-learned model comprises an artificial neural network.

15. The computer-implemented method of claim 1,
wherein the machine-learned model is trained using solutions generated by direct numerical simulations, large eddy simulations, or Reynolds-averaged Navier-Stokes simulations.

16. The computer-implemented method of claim 1,
wherein the machine-learned model is trained using solutions generated for Kolmogorov flows or decaying turbulence flows.

17. The computer-implemented method of claim 1,
wherein the machine-learned model is trained using coarsened versions of solutions generated by direct numerical simulations, and wherein the coarsened versions are generated by:
averaging points of the solutions generated by the direct numerical simulations;
subsampling points of the solutions generated by the direct numerical simulations according to a box filter, a Gaussian filter, or a sharp spectral filter; or
using an additional machine-learned model.

18. The computer-implemented method of claim 1, wherein the one or more differential equations describe electromagnetic fields, electromagnetic forces, electromagnetic potential, or electric charges, and wherein the one or more differential equations comprise one or more of Maxwell's equations.

19. (canceled)

20. An article of manufacture comprising a non-transitory, computer-readable medium having stored therein instructions executable by a computing device to cause the computing device to perform the computer-implemented method of any preceding claim 1.

21. A system comprising:
one or more processors; and
a non-transitory, computer-readable medium having stored therein instructions executable by the one or more processors to perform the computer-implemented method of claim 1.

22. The system of claim 21, wherein the one or more processors comprise a graphics processing unit (GPU) or a tensor processing unit (TPU).
